(19) United States
(12) Patent Application Publication
(10) Pub. No.: US 2025/0253640 A1
(43) Pub. Date: Aug. 7, 2025

(54) ELECTRONIC DEVICE WITH SHORT-CIRCUIT PROTECTION FUNCTION

(71) Applicant: WISTRON NEWEB CORPORATION, HSINCHU (TW)

(72) Inventor: FU-CHI CHUANG, HSINCHU (TW)

(21) Appl. No.: 19/008,752

(22) Filed: Jan. 3, 2025

(30) Foreign Application Priority Data
Feb. 6, 2024 (TW) 113104590

(51) Int. Cl. H02H 3/16; H02H 1/00

(52) U.S. Cl. CPC H02H 3/16; H02H 1/0007

(57) ABSTRACT

An electronic device with a short circuit protection function is provided. The electronic device includes a first switch, a detection circuit and a second switch. The first switch is disposed between an output node and an electronic component, a power converter provides an output voltage to the output node, and a to-be-protected circuit is connected to the output node. The detection circuit is configured to detect whether or not a short circuit failure occurs in the electronic component. The second switch is connected to a first control terminal of the first switch, and the second switch determines whether to control the first switch to be turned off according to a detection result of the detection circuit. In response to the detection circuit detecting that the short circuit failure occurs in the electronic component, the second switch is used to control the first switch to be turned off.

### CROSS-REFERENCE TO RELATED PATENT APPLICATION

This application claims the benefit of priority to Taiwan Patent Application No. 113104590, filed on Feb. 6, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a device, and more particularly to an electronic device with a short circuit protection function.

### BACKGROUND OF THE DISCLOSURE

The rapid advancement of technology and the ever-evolving development of electronic products have made modern life more convenient and efficient. However, alongside their advantages, electronic products also have some inevitable drawbacks.

For instance, the biggest issue with electronic products is the lifespan of electronic components. Some components may fail after a period of use due to their inherent characteristics. While a product may still be usable if an open-circuit failure occurs in the component, a short-circuit failure in the component can cause the product to malfunction altogether. Hence, a new concept is introduced for allowing other components to still be able to function normally even when a short circuit occurs in an electronic component.

Therefore, overcoming the challenge of ensuring that other components can continue to operate despite a short circuit failure occurring in certain electronic components has become one of important issues to be addressed in the relevant field.

### SUMMARY OF THE DISCLOSURE

In response to the above-referenced technical inadequacies, the present disclosure provides an electronic device with a short circuit protection function, and the electronic device ensures that other components can operate normally when a short circuit occurs in an electronic component.

In order to solve the above-mentioned problems, one of the technical aspects adopted by the present disclosure is to provide an electronic device with a short circuit protection function, and the electronic device includes a first switch, a detection circuit and a second switch. The first switch is disposed between an output node and an electronic component, a power converter provides an output voltage to the output node, and a circuit is connected to the output node. The detection circuit is configured to detect whether or not a short circuit failure occurs in the electronic component. The second switch is connected to a first control terminal of the first switch, and the second switch is configured to determine whether to control the first switch to be turned off according to a detection result of the detection circuit. In response to the detection circuit detecting that the short circuit failure occurs in the electronic component, the second switch is used to control the first switch to be turned off. In response to the detection circuit detecting that the short circuit failure does not occur in the electronic component, the second switch is used to control the first switch to be turned on.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a system architecture diagram of an electronic device with a short circuit protection function that is applied according to a first embodiment of the present disclosure;

FIG. 2 is a circuit diagram of a short circuit protection circuit according to the first embodiment of the present disclosure;

FIG. 3 is a circuit diagram of a short circuit protection circuit according to a second embodiment of the present disclosure; and

FIG. 4 is a system architecture diagram of an electronic device using the short circuit protection circuit of the second embodiment of the present disclosure.

### DETAILED DESCRIPTION OF THE EXEMPLARY EMBODIMENTS

The following is a specific embodiment to illustrate the implementation of the “electronic device with short circuit protection function” disclosed in the present disclosure. Those skilled in the art can understand the advantages and effects of the present disclosure from the contents disclosed in this specification. The present disclosure may be implemented or applied through other different specific embodiments, and the details in this specification may be modified and changed in various ways based on different viewpoints and applications without departing from the concept of the present disclosure. In addition, the drawings of the present disclosure are for simple illustration only and are not depictions of actual sizes. Please note in advance. The following embodiments will further illustrate the relevant technical contents of the present disclosure, but the disclosed contents are not intended to limit the protection scope of the present disclosure. In addition, the term “or” used herein may include any one or more combinations of the associated listed items as appropriate. In addition, the term “connected” throughout the present disclosure means that there is a physical connection between two elements and it can be a direct connection or an indirect connection.

A person of ordinary skill in the art is capable of identifying resistor symbols, comparator symbols, metal-oxide semiconductor field effect transistor (MOSFET) symbols, and bipolar junction transistor (BJT) symbols, especially P-type and N-type MOSFETs and NPN and PNP-type BJTs, and capable of identifying the “source”, “gate” and “drain” terminals of MOSFETs. Furthermore, a person having ordinary skill in the art is capable of reading the schematic diagrams of the circuits including resistors, capacitors, N-type MOSFETs and P-type MOSFETs in the present disclosure without needing a detailed description of how the transistors, resistors or capacitors in the above schematic diagrams are connected to other transistors, resistors or capacitors.

### First Embodiment

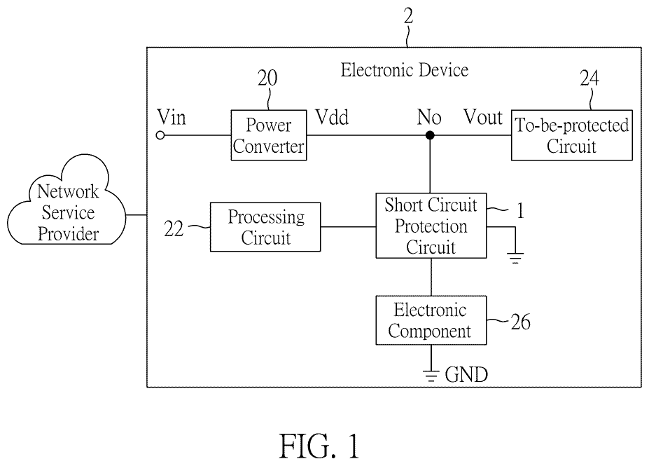

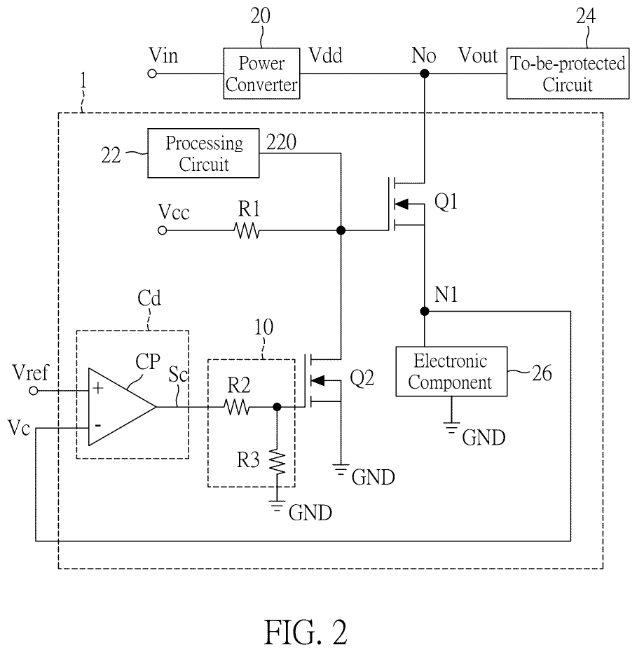

FIG. 1 is a system architecture diagram of an electronic device with a short circuit protection function that is applied according to a first embodiment of the present disclosure, and FIG. 2 is a circuit diagram of a short circuit protection circuit according to the first embodiment of the present disclosure.

Referring to FIGS. 1 and 2, a first embodiment of the present disclosure provides a short circuit protection circuit 1 that can be applied to a system architecture of an electronic device 2 as shown in FIG. 1. The electronic device 2 can be, for example, a network electronic device that can be connected to a network service provider, and the electronic device 2 includes a power converter 20, a processing circuit 22, a to-be-protected circuit 24, and an electronic component 26.

The power converter 20 can be, for example, a boost, buck or buck-boost converter for converting the input voltage Vin to provide a common voltage Vdd with various levels as an output voltage Vout at an output node No according to requirements of various components (such as the to-be-protected circuit 24) in the electronic device 2.

The electronic component 26 is connected between a ground terminal and the output node No. The electronic component 26 can be, for example, an electrolytic capacitor, which is widely used in various types of electronic devices. Although the electrolytic capacitors have advantages such as large capacity, high voltage and high pulse current resistance, and low cost, they are prone to short circuiting after long-term use. Therefore, the short circuit protection circuit 1 is designed for the electronic component 26 that may have a short circuit failure.

The processing circuit 22 can be, for example, a central processing unit built into various electronic devices, and the processing circuit 22 is responsible for managing an operation of the electronic device 2 and can perform various simple or complex calculations and processing procedures.

An over-current protection mechanism is usually designed inside or outside the power converter 20. When the electronic component 26 of FIG. 1 experiences a short circuit failure due to long-term use, the over-current protection mechanism of the power converter 20 will detect the over-current and stop outputting the common voltage Vdd, causing the to-be-protected circuit 24 to be unable to operate normally. In some electronic devices 2, the power converter 20 can be electrically connected to the processing circuit 22 to notify the processing circuit 22 when the over-current protection mechanism is triggered.

In order to prevent the over-current protection mechanism of the power converter 20 from being triggered when the electronic component 26 is short-circuited, the short-circuit protection circuit 1 provided by the present disclosure can be disposed between the output node No and the electronic component 26, and can be electrically connected to the processing circuit 22.

Referring to FIG. 2, the short circuit protection circuit 1 provided in the first embodiment of the present disclosure can include a first switch Q1, a detection circuit Cd and a second switch Q2.

The first switch Q1 and the second switch Q2 can each be a MOSFET or a BJT. In the embodiment of FIG. 2, the first switch Q1 and the second switch Q2 are both NMOSFETs. The first switch Q1 is disposed between the output node No and the electronic component 26. The power converter 20 provides the common voltage Vdd to the output node No as the output voltage Vout, and the to-be-protected circuit 24 is connected to the output node No.

The first switch Q1 has a first terminal, a second terminal and a first control terminal (i.e., a drain, a source and a gate). The first terminal is connected to the output node No, and the second terminal is connected to the electronic component 26 through the first node N1. The electronic component 26 is connected between the second terminal of the first switch Q1 and the ground terminal GND. The detection circuit Cd can be disposed between the first node N1 and the second switch Q2 to detect whether or not a short circuit failure occurs in the electronic component 26.

The second switch Q2 has a first terminal, a second terminal and a second control terminal (i.e., a drain, a source and a gate), and the first terminal of the second switch Q2 is connected to the first control terminal of the first switch Q1, the second terminal of the second switch Q2 is connected to the ground terminal GND, and the second control terminal is connected to the detection circuit Cd. The second switch Q2 can determine whether to control the first switch Q1 to be turned off or turned on according to a detection result of the detection circuit Cd.

In summary, when the detection circuit Cd detects that the short circuit failure occurs in the electronic component 26, the second switch Q2 can control the first switch Q1 to be turned off. On the contrary, when the detection circuit Cd detects that the short circuit failure does not occur in the electronic component 26, the second switch Q2 can control the first switch Q1 to be turned on.

In the embodiment of FIG. 2, the detection circuit Cd can include a comparator CP having a first input terminal (a negative input terminal), a second input terminal (a positive input terminal) and an output terminal. The first input terminal of the comparator CP is connected to a first node N1 between the first switch Q1 and the electronic component 26, the second input terminal of the comparator CP is used to receive a reference voltage Vref (for example, the second input terminal can be connected to a reference voltage source), and the output terminal of the comparator CP is connected to the second control terminal of the second switch Q2.

In addition, the processing circuit 22 can also be regarded as a part of the short circuit protection circuit 1, and the processing circuit 22 has a detection terminal 220. The detection terminal 220 is connected to the first control terminal of the first switch Q1, the first terminal of the second switch Q2 and a first operating voltage Vcc.

As shown in FIG. 2, the short circuit protection circuit 1 further includes a first resistor R1 and a first voltage divider circuit 10. The first resistor R1 is connected between the first operating voltage Vcc and the detection terminal 220, and is used to adjust the voltage that turns on the first switch Q1. The first voltage dividing circuit 10 includes a second resistor R2 and a third resistor R3. The second resistor R2 is disposed between the comparator CP of the detection circuit Cd and the second control terminal of the second switch Q2. The third resistor R3 is disposed between the second control terminal of the second switch Q2 and the ground terminal GND. It should be noted that in this embodiment, all ground terminals GND are configured as a common ground, but the present disclosure is not limited thereto.

Specifically, the comparator CP is mainly used to compare a voltage Vc of the first node NI with the reference voltage Vref, thereby determining whether to control the second switch Q2 to be turned on by using a control signal Sc. For example, in the structure of FIG. 2, when a short circuit failure occurs in the electronic component 26, the comparator CP can determine that the voltage Vc at the first input terminal (i.e., the first node N1) is lower than the reference voltage Vref and generate the control signal Sc to turn on the second switch Q2; when a short circuit failure does not occur in the electronic component 26, the comparator CP can determine that the voltage Vc is higher than the reference voltage Vref and does not generate a control signal Sc, but instead pulls down a voltage of the second control terminal through the ground terminal GND, thereby turning off the second switch Q2.

More specifically, when the detection circuit Cd (i.e., the comparator CP) detects that the short circuit failure occurs in the electronic component 26, the second switch Q2 can be turned on to lower a voltage level of the first control terminal through the ground terminal GND, such that the first switch Q1 is turned off. In this case, since the first switch Q1 is turned off, the voltage of the output node No will no longer be affected by the short circuit failure of the electronic component 26, thereby preventing the output voltage Vout from being affected. When the detection circuit Cd (i.e., the comparator CP) detects that the short circuit failure does not occur in the electronic component 26, the second switch Q2 is turned off. In this case, the voltage of the first control terminal is pulled from the first operating voltage Vcc to a high voltage level, such that the first switch Q1 is turned on.

In the above embodiments, the common voltage Vdd can be the same as the output voltage Vout, for example, 5V, the first operating voltage Vcc can be smaller than the common voltage Vdd and the output voltage Vout, for example, 3.3V, and the reference voltage Vref can be smaller than the common voltage Vdd, the output voltage Vout and the first operating voltage Vcc, for example, 1.5V. It should be noted that a relationship between the reference voltage Vref and the voltage Vc of the first node N1 needs to be properly designed, such that the comparator CP can correctly determine whether the short circuit fault occurs in the electronic component 26 according to a state of the first node N1.

From the above, it can be seen that the voltage Vc is higher than the reference voltage Vref (=1.5V) when the short circuit failure does not occur in the electronic component 26, such that the comparator CP turns off the second switch Q2 through the ground terminal GND instead of outputting a high-level voltage while the first switch Q1 is turned on; when the short circuit failure occurs in the electronic component 26, the voltage Vc is lower than the reference voltage Vref, such that the comparator CP outputs a high-level voltage to turn on the second switch Q2, while the first switch Q1 is turned off. In this case, the common voltage Vdd can still provide the output voltage Vout as a power supplied to the to-be-protected circuit 24 without being affected by the short circuit failure of the electronic component 26. At the same time, the processing circuit 22 can be informed that the electronic component 26 has failed from a voltage change of the detection terminal 220 (i.e., from a high level corresponding to the first operating voltage Vcc to a low level).

In some embodiments, the processing circuit 22 can determine whether the short circuit failure occurs in the electronic component 26 according to the voltage of the detection terminal 220, and generate a fault indication signal accordingly. In this case, the electronic device 2 can inform the network service provider through the network that the electronic component 26 has a short circuit failure and may be damaged, so as to decide whether to replace the damaged component. In other embodiments, the electronic device 2 can also generate a warning signal, for example, an indicator light provided on the electronic device 2 can emit an indicator light signal, or a speaker provided on the electronic device 2 can make a warning sound, so as to inform the user of the short circuit failure.

### Second Embodiment

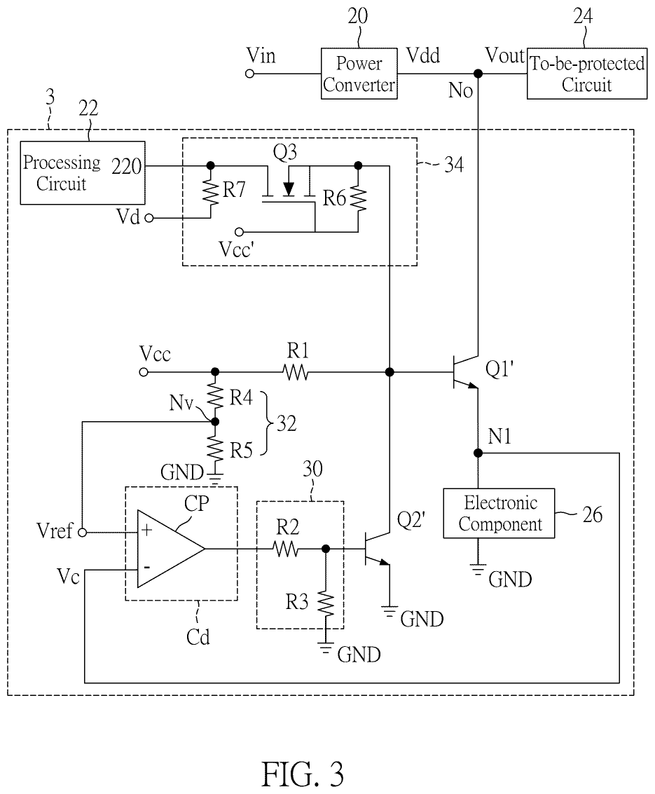

FIG. 3 is a circuit diagram of a short circuit protection circuit according to a second embodiment of the present disclosure. Referring to FIG. 3, a second embodiment of the present disclosure provides a short circuit protection circuit 3, which can be applied to the electronic device 2 in FIG. 1. It should be noted that the circuit structure of FIG. 3 is based on FIG. 2, and thus similar components are marked with similar reference numerals.

As shown in FIG. 3, the short circuit protection circuit 3 can include a first switch Q1′, a detection circuit Cd, a second switch Q2′, a first voltage dividing circuit 30, a second voltage dividing circuit 32 and a voltage conversion circuit 34. In the embodiment of FIG. 3, both the first switch Q1′ and the second switch Q2′ are NPN type BJTs. Similarly, the first switch Q1′ is disposed between the output node No and the electronic component 26, a power converter 20 provides a common voltage Vdd to the output node No as the output voltage Vout, and the to-be-protected circuit 24 is connected to the output node No.

The first switch Q1′ has a first terminal, a second terminal and a control terminal (i.e., a collector, an emitter and a base). The first terminal of the first switch Q1′ is connected to the output node No, and the second terminal of the first switch Q1′ is connected to the electronic component 26 through the first node N1. The electronic component 26 is connected between the second terminal of the first switch Q1′ and the ground terminal GND. The detection circuit Cd can be disposed between the first node N1 and the second switch Q2′ to detect whether or not a short circuit failure occurs in the electronic component 26.

The second switch Q2′ has a first terminal, a second terminal and a second control terminal (i.e., a collector, an emitter and a base), and the first terminal of the second switch Q2′ is connected to the first control terminal of the first switch Q1′, the second terminal of the second switch Q2′ is connected to the ground terminal GND, and the second control terminal is connected to the detection circuit Cd. The second switch Q2′ can determine whether to control the first switch Q1′ to be turned off or turned on according to a detection result of the detection circuit Cd.

In the embodiment of FIG. 3, the detection circuit Cd can include a comparator CP having a first input terminal (a negative input terminal), a second input terminal (a positive input terminal) and an output terminal. The first input terminal of the comparator CP is connected to a first node N1 between the first switch Q1′ and the electronic component 26, the second input terminal of the comparator CP is used to receive a reference voltage Vref, and the output terminal of the comparator CP is connected to the second control terminal of the second switch Q2′.

Different from the first embodiment, the reference voltage Vref is generated by the second voltage dividing circuit 32. Specifically, the second voltage dividing circuit 32 includes a fourth resistor R4 and a fifth resistor R5. One terminal of the fourth resistor R4 is connected to the first operating voltage Vcc, and another terminal of the fourth resistor R4 is connected to the fifth resistor R5. The fifth resistor R5 is connected between the fourth resistor R4 and the ground terminal GND.

Furthermore, the second input terminal (positive input terminal) of the comparator CP is connected to a voltage dividing node Nv between the fourth resistor R4 and the fifth resistor R5, and a divided voltage generated by the first operating voltage Vcc at the voltage dividing node Nv is used as the reference voltage Vref.

In addition, the processing circuit 22 can also be regarded as a part of the short circuit protection circuit 3 of the present disclosure, and the processing circuit 22 has a detection terminal 220. Different from the first embodiment, the detection terminal 220 can be connected to the voltage conversion circuit 34. The voltage conversion circuit 34 includes a third switch Q3, a sixth resistor R6, and a seventh resistor R7. The third switch Q3 can be a MOSFET or a BJT, and in the embodiment of FIG. 3, an NMOSFET is used. The third switch Q3 has a first terminal, a second terminal and a third control terminal (i.e., a drain, a source and a gate). The first terminal of the third switch Q3 is connected to the detection terminal 220, the second terminal of the third switch Q3 is connected to the first control terminal of the first switch Q1′, and the third control terminal of the third switch Q3 is connected to the second terminal through the sixth resistor R6.

In addition, the detection terminal 220 is also connected to a second operating voltage Vd through the seventh resistor R7, and the third control terminal of the third switch Q3 is also connected to a third operating voltage Vcc′. Here, the first operating voltage Vcc is different from the second operating voltage Vd, but can be the same as the third operating voltage Vcc′.

It should be noted that the voltage conversion circuit 34 here is a circuit structure added according to the actual application. For example, when a voltage set at the detection terminal 220 of the processing circuit 22 (for example, the second operating voltage Vd) is different from the voltage used to turn on the second switch Q2′ (for example, the third operating voltage Vcc′), a voltage conversion can be performed by the voltage conversion circuit 34. Otherwise, a voltage variation range of the detection terminal 220 may exceed a range that the processing circuit 22 can detect, which will cause the processing circuit 22 to be unable to determine whether the first switch Q1′ is turned off based on the voltage variation of the detection terminal 220.

As shown in FIG. 3, the first resistor R1 and the first voltage dividing circuit 30 of the short circuit protection circuit 3 are similar to those in FIG. 2, and thus repeated descriptions are omitted herein. Similarly, the comparator CP is mainly used to compare the voltage Vc of the first node N1 with the reference voltage Vref to determine whether a voltage can be output as the control signal Sc. For example, in the structure of FIG. 3, when a short circuit failure occurs in the electronic component 26, the comparator CP can determine that the voltage Vc at the first input terminal (i.e., the first node N1) is lower than the reference voltage Vref and generate the control signal Sc to turn on the second switch Q2′; when the short circuit failure does not occur in the electronic component 26, the comparator CP can determine that the voltage Vc is higher than the reference voltage Vref and does not generate a control signal Sc, but instead pulls down a voltage of the second control terminal through the ground terminal GND, thereby turning off the second switch Q2.

More specifically, when the detection circuit Cd (i.e., the comparator CP) detects that the short circuit failure occurs in the electronic component 26, the second switch Q2′ can be turned on to lower a voltage level of the first control terminal through the ground terminal GND, such that the first switch Q1′ is turned off; when the detection circuit Cd (i.e., the comparator CP) detects that the short circuit failure does not occur in the electronic component 26, the second switch Q2′ can be turned off, the voltage of the first control terminal is pulled from the first operating voltage Vcc to a high voltage level, such that the first switch Q1′ is turned on.

It should be noted that a resistance of the sixth resistor R6 in the voltage conversion circuit 34 needs to be designed, such that when the short circuit failure does not occur in the electronic component 26 and the voltage of the first control terminal is at a high level, the third switch Q3 is turned off, and the processing circuit 22 can receive the second operating voltage Vd through the detection terminal 220. When the short circuit failure occurs in the electronic component 26, the voltage of the first control terminal is pulled to a ground voltage by the ground terminal GND, and a voltage difference caused by the sixth resistor R6 can make a voltage difference between the second terminal and the third control terminal of the third switch Q3 (i.e., a source-gate voltage) greater than a threshold voltage of the third switch Q3, such that the third switch Q3 is turned on.

In the above embodiment, the common voltage Vdd can be the same as the output voltage Vout, such as 5V, the first operating voltage Vcc can be smaller than the common voltage Vdd and the output voltage Vout, such as 3.3V, and the reference voltage Vref can be 1.5V, for example. It should be noted that a relationship between the reference voltage Vref and the voltage Vc of the first node N1 needs to be properly designed, such that the comparator CP can correctly determine whether the short circuit fault occurs in the electronic component 26 according to a state of the first node N1.

For example, if a voltage range that the processing circuit 22 can withstand is close to 1.8V, and the third operating voltage Vcc′ being 3.3V may be greater than an upper limit of the voltage range, and therefore the detection mechanism of the processing circuit 22 may not able to function normally. Therefore, it is necessary to additionally provide the voltage conversion circuit 34, such that when the third switch Q3 of the processing circuit 22 is turned off, the voltage at the detection terminal 220 is 1.8V (i.e., the second operating voltage Vd), and when the third switch Q3 is turned on, the voltage at the detection terminal 220 is the ground voltage, thereby allowing the detection mechanism of the processing circuit 22 to function normally.

From the above, it can be seen that when the short circuit failure does not occur in the electronic component 26, the voltage Vc is higher than the reference voltage Vref (=1.5V), such that the comparator CP does not output a high-level voltage, but turns off the second switch Q2 through the ground terminal GND, while the first switch Q1′ is turned on; when the short circuit failure occurs in the electronic component 26, the voltage Vc is lower than the reference voltage Vref, such that the comparator CP outputs a high-level voltage to turn on the second switch Q2′, while the first switch Q1′ is turned off. In this case, the common voltage Vdd can still provide the output voltage Vout as a power supplied to the to-be-protected circuit 24 without being affected by the short circuit failure of the electronic component 26. At the same time, the processing circuit 22 can be informed that the short circuit failure has occurred from the voltage change of the detection terminal 220 (i.e., from a high level corresponding to the second operating voltage Vd to a low level).

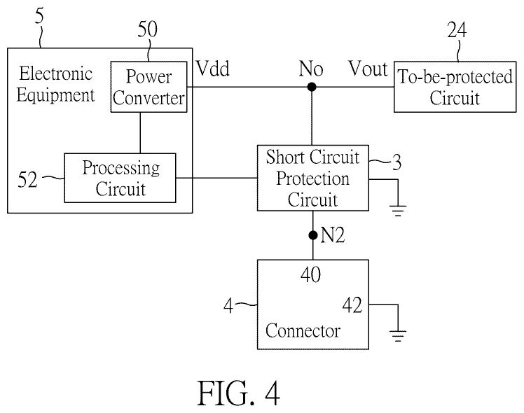

FIG. 4 is a system architecture diagram of an electronic device using the short circuit protection circuit of the second embodiment of the present disclosure. As shown in FIG. 4, the short circuit protection circuit 3 provided by the present disclosure can also be applied to a commonly used connector 4 (e.g., a USB connector), which has a power pin 40 and a ground pin 42. When the connector 4 is connected to the electronic device 5 through the short circuit protection circuit 3 and is powered by the power converter 50, the short circuit protection circuit 3 can cut off a path connecting the second node N2 (corresponding to the first node N1 of the aforementioned embodiment) to the connector 4 through the aforementioned detection mechanism when a short circuit failure occurs in the connector 4 (e.g., the short circuit failure occurs between the power pin 40 and the ground pin 42). In this way, the to-be-protected circuit 24 can be prevented from being affected by the short circuit failure of the connector 4 and affecting its normal operation.

### Beneficial Effects of Embodiments

In conclusion, in the electronic device with short circuit protection function provided by the present disclosure, when a short circuit failure occurs in the electronic component, the comparator can properly control switch circuits that are accordingly designed, such that the power converter can still provide an output voltage as a power source to the to-be-protected circuit without being affected by the short circuit failure of the electronic component.

Furthermore, the electronic device with short circuit protection function provided by the present disclosure can also be provided with one or more voltage dividing circuits and a voltage conversion circuit, so as to provide appropriate voltages to the processing circuit and the comparator as needed, such that the comparator can correctly determine whether the short circuit failure occurs in the electronic component based on states of specific nodes, while being able to meet original voltage specifications of the processing circuit.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An electronic device with a short circuit protection function, the electronic device comprising:
a first switch disposed between an output node and an electronic component, wherein a power converter provides an output voltage to the output node, and a circuit is connected to the output node;
a detection circuit configured to detect whether or not a short circuit failure occurs in the electronic component; and
a second switch connected to a first control terminal of the first switch, wherein the second switch is configured to determine whether to control the first switch to be turned off or turned on according to a detection result of the detection circuit;
wherein, in response to the detection circuit detecting that the short circuit failure occurs in the electronic component, the second switch is used to control the first switch to be turned off, and in response to the detection circuit detecting that the short circuit failure does not occur in the electronic component, the second switch is used to control the first switch to be turned on.

2. The electronic device according to claim 1, wherein the first switch further has a first terminal connected to the output node and a second terminal connected to the electronic component, and the electronic component is connected between the second end of the first switch and a ground terminal.

3. The electronic device according to claim 2, wherein the second switch has a first terminal connected to the first control terminal, a second terminal connected to the ground terminal, and a second control terminal connected to the detection circuit.

4. The electronic device according to claim 3, further comprising:
a processing circuit having a detection terminal, wherein the detection terminal is connected to the first control terminal, the first terminal of the second switch, and a first operating voltage.

5. The electronic device according to claim 4, wherein, when the detection circuit detects that the short circuit failure occurs in the electronic component, the detection circuit controls the second switch to be turned on to turn off the first switch through the ground terminal, and when the detection circuit detects that the short circuit failure does not occur in the electronic component, the detection circuit controls the second switch to be turned off to turn on the first switch through the first operating voltage.

6. The electronic device according to claim 4, wherein the processing circuit is configured to determine whether or not the short circuit failure occurs in the electronic component based on a voltage at the detection terminal, and to generate a failure indication signal, accordingly.

7. The electronic device according to claim 4, further comprising:
a first resistor connected between the first operating voltage and the detection terminal, wherein the first resistor is used to adjust a voltage that turns on the first switch.

8. The electronic device according to claim 4, further comprising a first voltage dividing circuit, wherein the first voltage dividing circuit includes:
a second resistor disposed between the detection circuit and the second control terminal; and
a third resistor disposed between the second control terminal and the ground terminal.

9. The electronic device according to claim 4, wherein the detection circuit includes a comparator having a first input terminal connected between the first switch and the electronic component, a second input terminal connected to a reference voltage, and an output terminal connected to the second control terminal;
wherein, when the short circuit failure occurs in the electronic component, the comparator determines that a voltage of the first input terminal is lower than the reference voltage and generates a control signal to turn on the second switch.

10. The electronic device according to claim 9, further comprising a second voltage dividing circuit, wherein the second voltage dividing circuit includes:
a fourth resistor, wherein one terminal of the fourth resistor is connected to the first operating voltage; and
a fifth resistor connected between the fourth resistor and the ground terminal;
wherein the second input terminal is connected to a voltage dividing node between the fourth resistor and the fifth resistor, and a divided voltage generated by the first operating voltage at the voltage dividing node is used as the reference voltage.

11. The electronic device according to claim 10, wherein, when the short circuit failure does not occur in the electronic component, the comparator determines that the voltage of the first input terminal is higher than the reference voltage and does not generate the control signal, and the second switch is turned off through the ground terminal.

12. The electronic device according to claim 9, further comprising a voltage conversion circuit, wherein the voltage conversion circuit includes:
a third switch having a first terminal connected to the detection terminal, a second terminal connected to the first control terminal, and a third control terminal connected to the second terminal of the third switch through a sixth resistor, wherein the detection terminal is also connected to a second operating voltage through a seventh resistor, the third control terminal of the third switch is also connected to a third operating voltage, and the first operating voltage is different from the second operating voltage.

13. The electronic device according to claim 9, wherein the reference voltage is less than the output voltage.

14. The electronic device according to claim 1, wherein the first switch and the second switch are each a metal-oxide-semiconductor field-effect transistor or a bipolar junction transistor.
